(19) United States
(12) Patent Application Publication
(10) Pub. No.: US 2005/0069817 A1
(43) Pub. Date: Mar. 31, 2005

(54) Photolithographic method for manufacturing a mold for a light guide plate

(76) Inventors: Charles Leu, Fremont, CA (US); Tai-Cherng Yu, Tu-Chen (TW); Ga-lane Chen, Fremont, CA (US)

Correspondence Address: WEI TE CHUNG;FOXCONN INTERNATIONAL, INC., 1650 MEMOREX DRIVE, SANTA CLARA, CA, 95050, US

(21) Appl. No.: 10/951,528

(22) Filed: Sep. 27, 2004

(30) Foreign Application Priority Data
Sep. 26, 2003 (TW) 92126622

(51) Int. Cl. G03F 7/00

(52) U.S. Cl. 430/320; 430/323

(57) ABSTRACT

A method for manufacturing a mold for a light guide plate includes the steps of: providing a substrate (520); forming a photo-resist film (600) on the substrate; disposing a mask having a predetermined pattern over the substrate, illuminating the photo-resist film through the mask by illuminating rays; developing the photo-resist film to form a photo-resist pattern (640) on the substrate; dry-etching the substrate and the photo-resist pattern simultaneously to form a mold preform; and stripping the residual photo-resist pattern from the patterned substrate to attain the mold (500). The method is highly precise and relatively simple.

### CROSS-REFERENCE TO RELATED APPLICATION

This application is related to the application by Ga-Lane Chen, Kun-Jung Tsai and Tai-Cherng Yu, entitled METHOD FOR MANUFACTURING LIGHT GUIDE PLATE STAMPER filed in an earlier time, and assigned to the same assignee as the present application.

### BACKGROUND OF THE INVENTION

1. Field of the Invention

The present invention relates to method for manufacturing molds for light guide plates, and particularly to a method for manufacturing a mold for a light guide plate using photolithography technology.

2. Prior Art

In a liquid crystal display device, a backlight module is commonly used to provide a planar light source for illuminating the liquid crystal display. In general, the backlight module includes a light source and a light guide plate, the light source being located adjacent to one side of the light guide plate. The light guide plate transforms light beams emitted from the light source into planar light beams, and directs the planar light beams to a liquid crystal panel of the liquid crystal display device.

Typically, a plurality of dots is distributed on a bottom surface of the light guide plate, for improving the uniformity of illumination of the backlight module. The dots scatter and reflect the light beams, so that the light beams uniformly emit out from a light-emitting surface of the light guide plate. The shape, the density and the size of the dots are configured according to the requirements of different applications. For example, the dots can be cuboid, cylindrical, or frustum-shaped.

Presently, methods for manufacturing a light guide plate having dots are divided into two categories: printing methods and molding methods. The quality of a light guide plate made by a typical printing method is difficult to control. For this reason, printing methods are gradually being supplanted by molding methods, especially by injection-molding methods. In general, a mold of a light guide plate and an injection-molding device are necessary for carrying out an injection-molding method.

FIG. 5 shows a conventional method for manufacturing a mold for a light guide plate that has a plurality of dots. The method includes the steps of: spin coating a photo-resist film on a substrate; exposing and developing the photo-resist film to form a photo-resist pattern on the substrate; and etching the substrate and the photo-resist pattern with a kind of chemical solution (so-called “wet etching”) to thereby form the mold. However, wet etching is a kind of isotropic etching, in which the chemical reaction in the chemical solution is hard to control. Further, the etching time and the speed of the chemical reaction are difficult to control. Thus the precision of the mold may be mediocre, in which case the quality of the formed light guide plate is correspondingly low.

A new manufacturing method for a mold for a light guide plate that overcomes the above-mentioned disadvantages is desired.

### SUMMARY OF THE INVENTION

An object of the present invention is to provide a manufacturing method for a mold for a light guide plate which is highly precise and relatively simple.

In order to achieve the object set forth, a method for manufacturing a mold for a light guide plate in accordance with the present invention comprises the steps of: providing a substrate; forming a photo-resist film on the substrate; disposing a mask having a predetermined pattern over the substrate, and exposing the photo-resist film to illuminating rays through the mask; developing the photo-resist film to form a photo-resist pattern on the substrate; dry-etching the substrate and the photo-resist pattern simultaneously; and stripping the residual photo-resist pattern from the mold preform to obtain the mold. The mold defines highly precise rectangular grooves, so that the formed light guide plate has correspondingly precise diffusion dots integrally formed thereon. In addition, the manufacturing method requires relatively few and simple steps.

Other objects, advantages and novel features of the invention will become more apparent from the following detailed description when taken in conjunction with the accompanying drawings, in which:

### BRIEF DESCRIPTION OF THE DRAWINGS

FIG. 1 shows a step of spinning a photo-resist film on a substrate in a method for manufacturing a mold of light guide plate according to the present invention;

FIG. 2 shows a step of exposing and developing the photo-resist layer in the method for manufacturing the mold of light guide plate;

FIG. 3 shows an etching step in the method for manufacturing the mold of light guide plate;

FIG. 4 is a schematic view of a mold of light guide plate made by the method of the present invention; and

FIG. 5 is a flow chart of a conventional method of manufacturing a mold of light guide plate.

### DESCRIPTION OF THE PREFERRED EMBODIMENTS

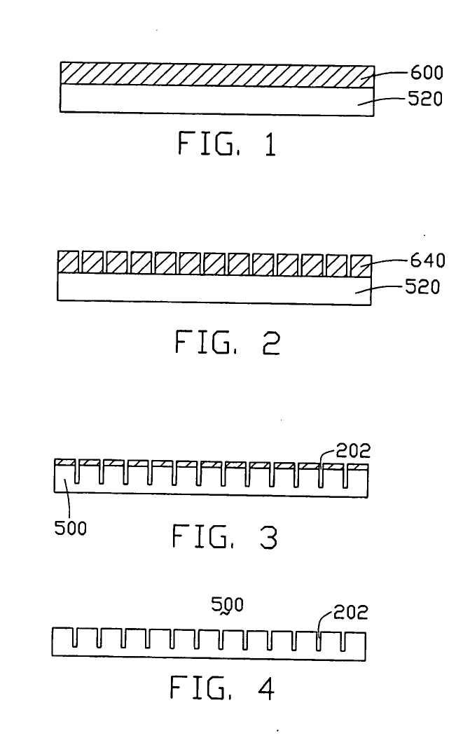

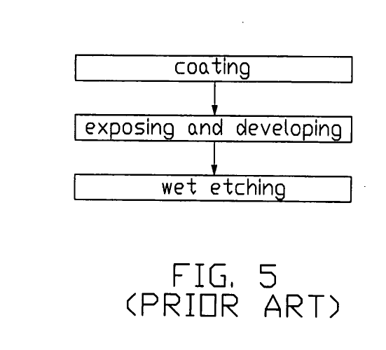

FIGS. 1 to 4 are views illustrating stages in a method for manufacturing a mold for a light guide plate according to the present invention. The mold enables the light guide plate to have a plurality of precise diffusion dots integrally formed thereon. The manufacturing method includes the following steps:
(1) forming a photo-resist film 600 on a substrate 520, as shown in FIG. 1;
(2) disposing a mask (not shown) having a predetermined pattern over the substrate 520, and exposing the photo-resist film 600 to light through the mask;
(3) developing the photo-resist film 600 to form a photo-resist pattern 640 on the substrate 520, as shown in FIG. 2;
(4) dry-etching the substrate 520 and the photo-resist pattern 640 simultaneously to form a mold preform having a plurality of generally rectangular grooves 202, as shown in FIG. 3; and
(5) stripping the residual photo-resist pattern 640 from the mold preform to obtain the mold 500 for a light guide plate, as shown in FIG. 4.

In the first step, the plate-like substrate 520 is provided. The substrate 520 is made of stainless steel, such as nickel steel or alnico alloyed nickel steel. A thin film layer (not shown) is formed on the substrate 520, to improve the smoothness of the substrate 520.

The photo-resist film 600 is formed on an upper surface of the substrate 520, as shown in FIG. 1. The photo-resist film 600 may be a positive or negative photo-resist material. The process for forming the photo-resist film 600 may be spin coating, dip coating, roll coating, spray coating, extrusion slot coating, etc.

In the second and third steps, the photo-resist film 600 is exposed to light and developed. Ultraviolet light rays illuminate the photo-resist film 600 through the mask (not shown) positioned over the photo-resist film 600. The mask is a partly transparent glass substrate having a predetermined pattern. Parts of the photo-resist film 600 are illuminated by the ultraviolet light rays and become photosensitized. Then, developing solution is sprayed on the photo-resist film 600. The photosensitized parts of the photo-resist film 600 are dissolved completely, due to chemical reaction between the photosensitized parts and the developing solution. The residual photo-resist film 600 forms the determined photo-resist pattern 640, which defines a plurality of apertures (not labeled) corresponding to a determined pattern desired for a light guide plate. The photo-resist pattern 640 is shown in FIG. 2.

In the fourth step, the substrate 520 and the photo-resist 640 are etched simultaneously using a dry-etching technique, to form patterns defining the rectangular grooves 202 in the substrate 520, as shown in FIG. 3. For example, plasma etching utilizes plasma driven by an alternating electric field to impinge on the substrate 520 and the photo-resist pattern 640 lying thereon. The plasma carves the precise rectangular grooves 202 in exposed surfaces of the substrate 520. Plasma gases are usually used as the driving gas, because they have high excitation energy. Plasma dry-etching technology has the advantage of anisotropic etching for most etching materials.

In the fifth step, the residual photo-resist pattern 640 is stripped. The mold 500 with the rectangular grooves 202 is thereby formed, as shown in FIG. 4. That is, the patterns of the mask are thus finally transferred to the mold 500.

The rectangular grooves 202 of the mold 500 etched by the dry-etching method have highly regular and precise profiles. This is because the etching is directed vertically down to the substrate 520, and portions of the substrate 520 under the photo-resist pattern 640 are not etched. Because the rectangular grooves 202 are highly regular and precise, a light guide plate made using the mold 500 is correspondingly precise. The formed light guide plate with integral diffusion dots has high quality and good optical performance. In addition, the manufacturing method requires relatively few and simple steps.

It is noted that the above-described method for manufacturing a mold for a light guide plate can be used not only to form a mold for a light guide plate having a plurality of diffusion dots, but also to form a mold for a light guide plate having any other desired pattern. The particular pattern desired can be obtained according to the particular configuration of the pattern of the mask used, and according to the particular etching process adopted.

It is also to be understood that the invention may be embodied in other forms without departing from the spirit thereof. Thus, the present examples and embodiments are to be considered in all respects as illustrative and not restrictive, and the invention is not to be limited to the details given herein.

1. A method for manufacturing a mold for a light guide plate, comprising the steps of:
providing a substrate;
forming a photo-resist film on the substrate;
disposing a mask having a predetermined pattern over the substrate, and illuminating the photo-resist film through the mask;
developing the photo-resist film to form a photo-resist pattern on the substrate;
dry-etching the substrate and the photo-resist pattern simultaneously to form a mold preform; and
stripping the residual photo-resist pattern from the mold preform to obtain the mold.

2. The method according to claim 1, wherein the photo-resist pattern formed by the developing step defines a plurality of grooves.

3. The method according to claim 1, wherein the photo-resist film is illuminated by ultraviolet rays.

4. The method according to claim 1, wherein the dry-etching performed is plasma dry-etching.

5. The method according to claim 1, further comprising the step of forming a thin film layer on the substrate before forming the photo-resist film on the substrate.

6. The method according to claim 1, wherein the photo-resist film is formed by spin coating.

7. The method according to claim 1, wherein the photo-resist film is formed by dip coating.

8. The method according to claim 1, wherein the photo-resist film is formed by roll coating.

9. The method according to claim 1, wherein the photo-resist film is formed by spray coating.

10. The method according to claim 1, wherein the photo-resist film is formed by extrusion slot coating.

11. The method according to claim 1, wherein the photo-resist film is a positive photo-resist material.

12. The method according to claim 1, wherein the photo-resist film is a negative photo-resist material.

13. A method for manufacturing a mold for a light guide plate, comprising the steps of:
providing a substrate;
forming a film on the substrate;
disposing a mask having a predetermined pattern over the substrate, and activating the film through the mask;
removing portions of the film to form a corresponding pattern on the substrate;
dry-etching the substrate according to the corresponding pattern to form a mold preform; and
stripping the residual photo-resist pattern from the mold preform to obtain the mold.

14. The method according to claim 13, wherein said corresponding pattern on the mask is essentially same as the predetermined pattern.

15. The method according to claim 13, wherein said corresponding pattern on the mask is essentially vertically aligned with said predetermined pattern.
